(19) United States
(12) Patent Application Publication
(10) Pub. No.: US 2015/0144993 A1
(43) Pub. Date: May 28, 2015

(54) POWER SEMICONDUCTOR DEVICE

(71) Applicant: SAMSUNG ELECTRO-MECHANICS CO., LTD., Suwon-Si (KR)

(72) Inventors: Kee Ju Um, Suwon-Si (KR); In Hyuk Song, Suwon-Si (KR); Jae Hoon Park, Suwon-Si (KR); Chang Su Jang, Suwon-Si (KR); Ji Yeon Oh, Suwon-Si (KR)

(73) Assignee: SAMSUNG ELECTRO-MECHANICS CO., LTD., Suwon-Si (KR)

(21) Appl. No.: 14/292,297

(22) Filed: May 30, 2014

(30) Foreign Application Priority Data
Nov. 28, 2013 (KR) 10-2013-0146404

(51) Int. Cl. H01L 29/06; H01L 29/66; H01L 29/739

(52) U.S. Cl. CPC H01L 29/0661; H01L 29/7395; H01L 29/66348
USPC 257/139

(57) ABSTRACT

A power semiconductor device may include: an active region having a current flowing through a channel formed therein at the time of a turn-on operation of the power semiconductor device; a termination region formed in the vicinity of the active region; a plurality of first trenches formed lengthwise in one direction in the active region; and at least one or more second trenches formed lengthwise in one direction in the termination region. The second trench has a depth deeper than that of the first trench.

### CROSS-REFERENCE TO RELATED APPLICATION

This application claims the benefit of Korean Patent Application No. 10-2013-0146404 filed on Nov. 28, 2013, with the Korean Intellectual Property Office, the disclosure of which is incorporated herein by reference.

### BACKGROUND

The present disclosure relates to a power semiconductor device.

An insulated gate bipolar transistor (IGBT) is a transistor which has a gate fabricated using metal oxide silicon (MOS) and has a bipolar properties implemented therein through a p-type collector layer being formed on a rear surface thereof.

Since power metal oxide silicon field emission transistors (MOSFETs) were developed in the related art, such MOSFETs have been used in applications in which fast switching characteristics are required.

However, since MOSFETs have structural limitations, a bipolar transistor, a thyristor, a gate turn-off thyristor (GTO), and the like have been used in applications in which high voltages are required.

IGBTs have features such as a low forward loss and fast switching speeds, and therefore, the use thereof has tended to be expanded into applications for which typical thyristors, bipolar transistors, metal oxide silicon field emission transistors (MOSFETs), and the like may not be appropriate.

Describing an operational principle of the IGBT, in the case in which the IGBT device is turned on, when an anode has a voltage higher than that applied to a cathode applied thereto and a voltage higher than a threshold voltage of the IGBT device is applied to a gate electrode, a polarity of a surface of a p-type well layer, formed at a lower end of the gate electrode is inverted, and thus an n-type channel is formed.

An electron current injected into a drift region through the channel induces the injection of a hole current from a high-concentration p-type collector layer positioned below the IGBT device, similar to a base current of the bipolar transistor.

Due to injection of these minority carriers at a high concentration, a conductivity modulation which increases conductivity in the drift region by several times to hundreds of times due to an injection of minor carriers at high concentration may occur.

Unlike MOSFETs, IGBTs have a very small resistance component in the drift region due to such conductivity modulation, and therefor may be used in at very high voltages.

A current flowing in the cathode is divided into an electron current flowing through the channel and a hole current flowing through a junction between a p-type body and an n-type drift region.

Since the IGBT has a p-n-p structure between the anode and the cathode, a diode is not embedded in the IGBT unlike the MOSFET, such that a separate diode should be connected to the IGBT in reverse parallel.

The IGBT allows for characteristics such as maintenance of blocking voltages, decreases in conduction loss, and increases in switching speeds.

Particularly, in order to maintain a blocking voltage, a termination region is formed in the vicinity of an active region in which a current flows at the time of an operation of the IGBT.

Since an overall size of a power semiconductor device is limited, in the case in which the termination region is increased in the power semiconductor device, an active region of the power semiconductor device is decreased, such that performance of the power semiconductor device is deteriorated.

Therefore, a method capable of decreasing a size of the termination region of the power semiconductor device while sufficiently maintaining the blocking voltage of the power semiconductor device has been demanded.

Patent Document 1, related to a semiconductor device having a junction structure, discloses that a peripheral region has a blocking voltage higher than that of a cell region.

### RELATED ART DOCUMENT

(Patent Document 1) Korean Patent Laid-Open Publication No. 2006-0066655

### SUMMARY

An aspect of the present disclosure may provide a power semiconductor device having an improved blocking voltage and a small termination region.

According to an aspect of the present disclosure, a power semiconductor device may include: an active region having a current flowing through a channel formed therein at the time of a turn-on operation of the power semiconductor device; a termination region formed in the vicinity of the active region; a plurality of first trenches formed lengthwise in one direction in the active region; and at least one or more second trenches formed lengthwise in one direction in the termination region, wherein the second trench is formed to a depth deeper than that of the first trench.

The second trench may have a width greater than that of the first trench.

The second trench may have an insulating material filled therein.

The second trench may include an insulating layer formed on a surface thereof and a conductive material filled therein.

The power semiconductor device may further include an metal emitter layer formed on the active region, where the second trench has the same potential as that of the metal emitter layer.

The power semiconductor device may further include an electric field limiting region enclosing the second trenches and having a second conductive type.

The second trenches may be reduced in depth away from the active region.

According to another aspect of the present disclosure, a power semiconductor device may include: an active region having a current flowing through a channel formed therein at the time of a turn-on operation of the power semiconductor device; a termination region formed in the vicinity of the active region; a hole accumulating region formed in the active region and formed below the channel of the active region; a plurality of first trenches formed lengthwise in one direction in the active region; and at least one or more second trenches formed lengthwise in one direction in the termination region, wherein the second trench is formed to a depth deeper than that of the first trench.

The second trench may have a width greater than that of the first trench.

The second trench may have an insulating material filled therein.

The second trench may include an insulating layer formed on a surface thereof and a conductive material filled therein.

The power semiconductor device may further include a metal emitter layer formed on the active region, where the second trench has the same potential as that of the metal emitter layer.

The power semiconductor device may further include an electric field limiting region enclosing the second trenches and having a second conductive type.

The electric field limiting region may cover at least a portion of the hole accumulating region positioned in the active region and the termination region.

The second trenches may be reduced in depth away from the active region.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic perspective view of a power semiconductor device according to an exemplary embodiment of the present disclosure;

FIGS. 2 through 7 are cross-sectional views schematically illustrating various examples of the power semiconductor device according to an exemplary embodiment of the present disclosure;

FIG. 8 is a schematic perspective view of a power semiconductor device according to another exemplary embodiment of the present disclosure; and

FIGS. 9 through 14 are cross-sectional views schematically illustrating various examples of the power semiconductor device according to another exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

A power switch may be implemented by any one of a power metal oxide semiconductor field effect transistor (MOSFET), an insulated gate bipolar transistor (IGBT), several types of thyristors, and devices similar to the above-mentioned devices. Most of new technologies disclosed herein will be described based on the IGBT. However, several exemplary embodiments of the present disclosure disclosed herein are not limited to the IGBT, but may also be applied to other types of power switch technologies including a power MOSFET and several types of thyristors in addition to the IGBT. Further, several exemplary embodiments of the present disclosure will be described as including specific p-type and n-type regions. However, conductive types of several regions disclosed herein may be similarly applied to devices having conductive types opposite thereto.

In addition, an n-type or a p-type used herein may be defined as a first conductive type or a second conductive type. Meanwhile, the first and second conductive types mean different conductive types.

Further, generally, ‘+’ means a state in which a region is heavily doped and ‘−’ means a state that a region is lightly doped.

Hereinafter, although the first conductive type will be called an n-type and the second conductive type will be called a p-type in order to make a description clear, the present disclosure is not limited thereto.

In the accompanying drawings, x, y, and z refer to a width direction, a length direction, and a depth direction, respectively.

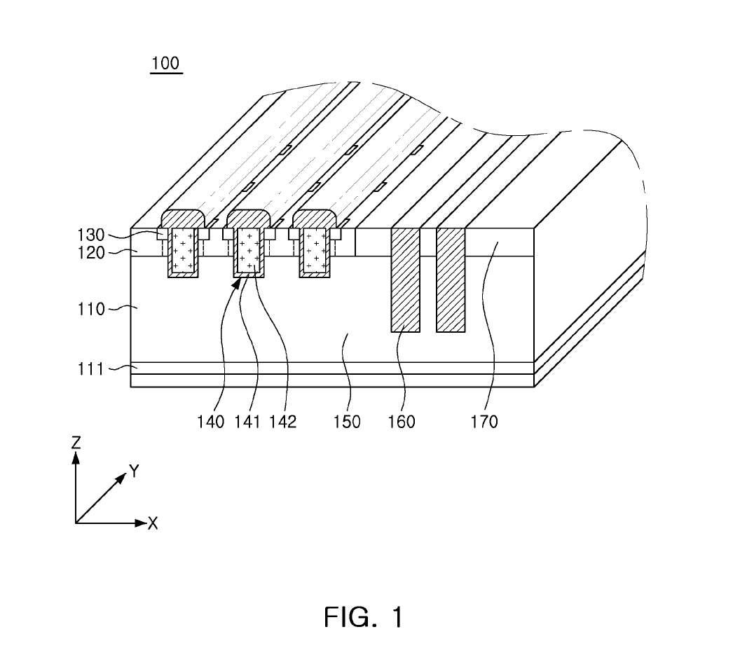

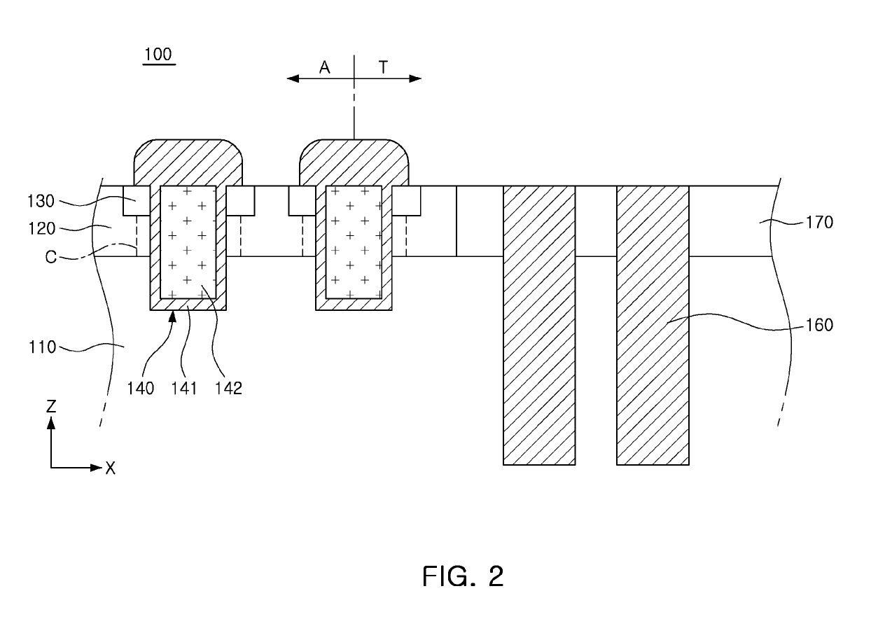

FIG. 1 is a schematic perspective view of a power semiconductor device 100 according to an exemplary embodiment of the present disclosure; and FIG. 2 is a schematic view illustrating an example of the power semiconductor device 100.

First, a structure of an active region A will be described.

The active region A may include a drift region 110, a body region 120, an emitter region 130, and a collector region 150.

The drift region 110 may be formed by implanting n-type impurities at a low concentration.

Therefore, the drift region 110 may have a relatively thick thickness in order to maintain a blocking voltage of the power semiconductor device.

The drift region 110 may further include a buffer region 111 formed therebelow.

The buffer region 111 may be formed by implanting n-type impurities into a rear surface of the drift region 110.

The buffer region 111 may serve to block extension of a depletion region of the power semiconductor device at the time of the extension of the depletion region, thereby assisting in maintaining a blocking voltage of the power semiconductor device.

Therefore, in the case in which the buffer region 111 is formed, a thickness of the drift region 110 may be decreased, such that the power semiconductor device may be miniaturized.

The drift region 110 may have the body region 120 formed thereon by implanting p-type impurities.

The body region 120 may have a conductive type corresponding to a p-type to form a pn junction with the drift region 110.

The body region 120 may have the emitter region 130 formed in an upper surface thereof by implanting n-type impurities at a high concentration.

First trenches 140 may be formed from the emitter region 130 to the drift region 110 through the body region 120.

That is, the first trenches 140 may penetrate from the emitter region 130 into a portion of the drift region 110 in the depth direction (z direction).

The first trenches 140 may be formed lengthwise in one direction (y direction) and may be arranged at predetermined intervals in a direction (x direction) perpendicular to the direction in which they are formed lengthwise.

The first trench 140 may have a gate insulating layer 142 formed at a portion at which it contacts the drift region 110, the body region 120, and the emitter region 130.

The gate insulating layer 141 may be formed of a silicon oxide (SiO₂), but is not limited thereto.

The first trench 140 may have a conductive material 142 filled therein.

The conductive material 142 may be a polysilicon (poly-Si) or a metal, but is not limited thereto.

The conductive material 142 may be electrically connected to a gate electrode (not shown) to control an operation of the power semiconductor device 100 according to an exemplary embodiment of the present disclosure.

In the case in which a positive voltage is applied to the conductive material 142, a channel C may be formed in the body region 120.

In detail, in the case in which the positive voltage is applied to the conductive material 142, electrons present in the body region 120 may be pulled toward the trench 140 and be collected in the trench 140, such that the channel C may be formed.

That is, electrons and holes may be recombined with each other due to a pn junction, such that the trench 140 pulls the electrons to in a depletion region in which carriers are not present to form the channel C, whereby a current may flow.

The drift region 110 or the buffer region 111 may have the collector region 150 formed therebelow by implanting p-type impurities.

In the case in which the power semiconductor device is the IGBT, the collector region 150 may provide holes to the power semiconductor device.

In the case in which the power semiconductor device is the MOSFET, the collector region 150 may have a conductive type corresponding to an n-type.

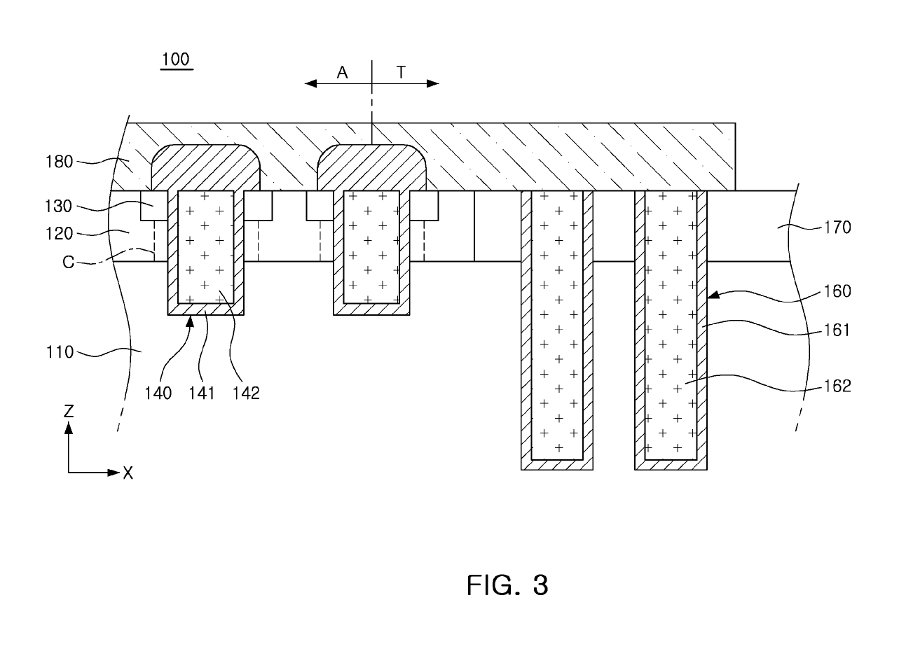

The emitter region 130 and the body region 120 may have an metal emitter layer 180 (See FIG. 3) formed on exposed upper surfaces thereof, and the collector region 150 may have a collector metal layer (not shown) formed on a lower surface thereof.

Next, a structure of a termination region T will be described.

The termination region T may have second trenches 160 formed therein.

The second trench 160 may be formed a depth deeper than that of the first trench.

That is, the second trench 160 may be formed by etching the drift region 110 at a depth deeper than that of the first trench 140.

Since the second trench 160 is formed at the depth deeper than that of the first trench 140, an electric field may be extended in the depth direction (z direction) in the power semiconductor device according to an exemplary embodiment of the present disclosure.

That is, since the electric field is extended in a vertical direction, a width of the termination region may be decreased as compared with the power semiconductor device according to the related art, and a blocking voltage may be sufficiently improved.

The second trench 160 may have an insulating material filled therein.

The insulating material may be a silicon oxide or a silicon nitride, but is not limited thereto.

The termination region T may have a second conductive-type guard ring 170 formed therein.

The guard ring 170 may maintain the blocking voltage in the width direction (x direction).

FIG. 3 is a schematic cross-sectional view illustrating another example of the power semiconductor device 100 according to an exemplary embodiment of the present disclosure including conductive materials 162 filled in the second trenches 160.

Referring to FIG. 3, the second trench 160 may have an insulating layer 161 formed on a surface thereof and may have the conductive material 162 filled therein.

Since the conductive material 162 filled in the trench 162 has an electric field of 0V, it may push the electric field.

Particularly, in the case in which the power semiconductor device 100 further includes the metal emitter layer 180 formed on the upper surfaces of the emitter region 130 and the body region 120, the emitting metal layer 180 and the second trench 160 may be electrically connected to each other.

In the case in which the metal emitter layer 180 and the second trench 160 are electrically connected to each other, the metal emitter layer 180 and the second trench 160 may have the same potential as each other.

Therefore, the second trench 160 may more easily push the electric field.

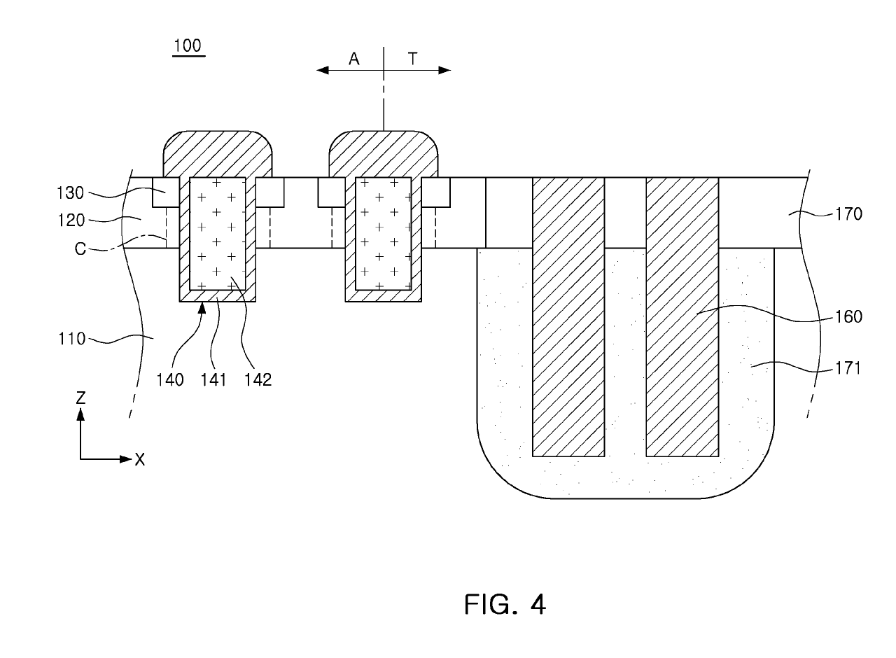

FIG. 4 is a schematic cross-sectional view illustrating another example of the power semiconductor device 100 according to an exemplary embodiment of the present disclosure including an electric field limiting region 171 formed in the vicinity of the second trenches 160.

Referring to FIG. 4, the electric field limiting region 171 may be formed by implanting p-type impurities in the vicinity of the second trenches 160.

The electric field limiting region 171 may be formed by etching the second trench and then implanting second conductive type impurities before filling an insulating material or a conductive material in the second trench.

In the case in which the trench is present, the electric field may be concentrated on a lower end portion of the trench due to a shape of the trench.

Therefore, the electric field limiting region 171 may be formed in the vicinity of the second trench 160 to prevent the electric field from being concentrated on the lower portion of the second trench 160, thereby improving a blocking voltage.

For example, the electric field limiting region 171 may be formed at only a lower end portion of the second trench 160 to prevent the electric field from being concentrated on the lower portion of the second trench 160, thereby improving the blocking voltage.

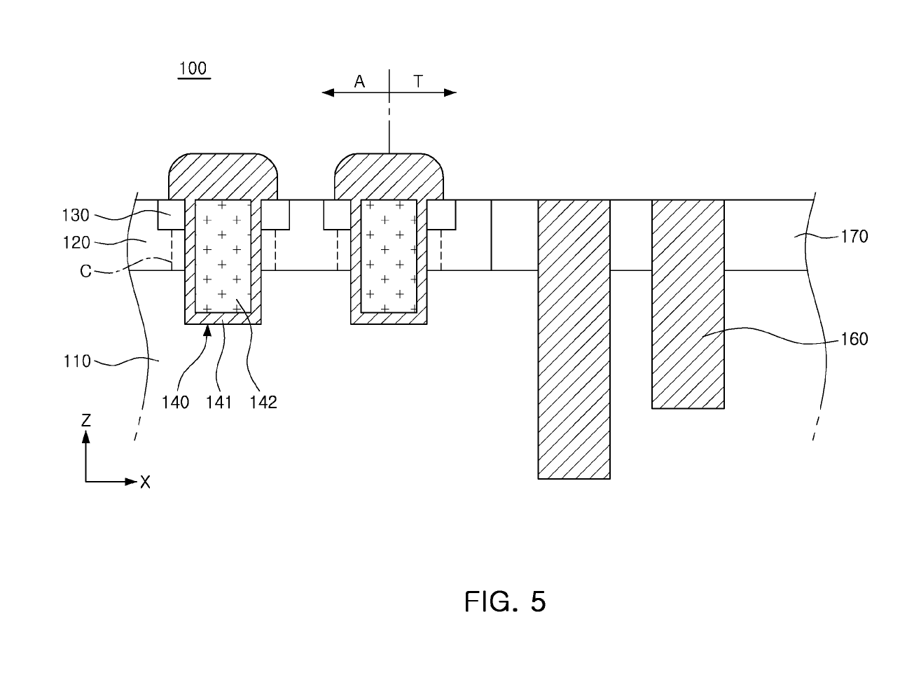

FIG. 5 is a schematic cross-sectional view illustrating another example of the power semiconductor device including second trenches 160 having depths that become shallow as they become distant from the active region A.

In the case in which two or more second trenches 160 are formed, they may have depths that become swallow as they are distant from the active region A.

Generally, the electric field may gradually become weak as it is distant from the active region.

Therefore, in the case in which the depths of the second trenches 160 become swallow as the second trenches 160 become distant from the active region A, as illustrated in FIG. 5, the blocking voltage may be more effectively improved and maintained.

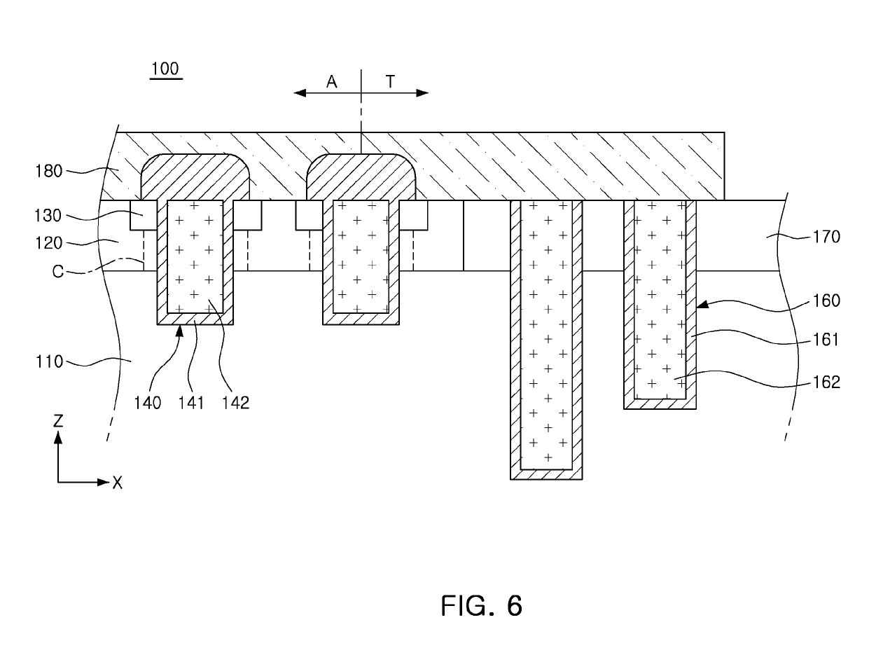

FIG. 6 is a schematic cross-sectional view illustrating another example of the power semiconductor device 100 including second trenches 160 having depths that become shallow as they become distant from the active region A and including conductive materials 162 filled in the second trenches 160.

Referring to FIG. 6, the second trench 160 may have an insulating layer 161 formed on a surface thereof and may have the conductive material 162 filled therein.

Since the conductive material 162 filled in the trench 162 has an electric field of 0V, it may push the electric field.

Particularly, in the case in which the power semiconductor device 100 further includes the metal emitter layer 180 formed on the upper surfaces of the emitter region 130 and the body region 120, the emitting metal layer 180 and the second trench 160 may be electrically connected to each other.

In the case in which the metal emitter layer 180 and the second trench 160 are electrically connected to each other, the metal emitter layer 180 and the second trench 160 may have the same potential as each other.

Therefore, the second trench 160 may more easily push the electric field.

In addition, in the case in which the depths of the second trenches 160 become swallow as the second trenches 160 become distant from the active region A, as illustrated in FIG. 6, the blocking voltage may be more effectively improved and maintained.

That is, in the case in which the second trench 160 is connected to the metal emitter layer 180 to have the same potential as that of the metal emitter layer 180, it may efficiently push the electric field. In this example, since the depths of the second trenches 160 become swallow as the second trenches 160 become distant from the active region A, a space in which the electric field is extended may be increased to improve the blocking voltage.

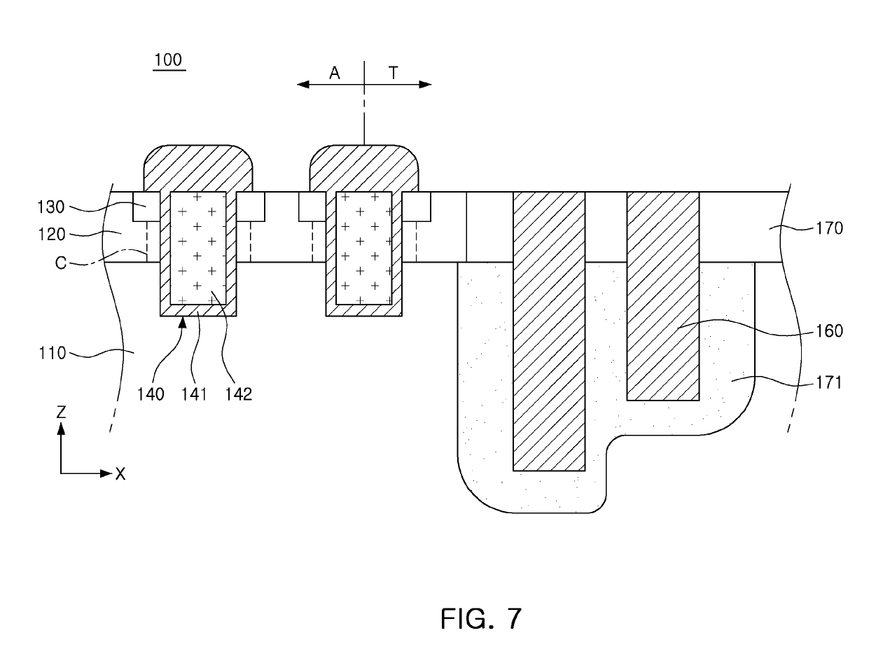

FIG. 7 is a schematic cross-sectional view illustrating another example of the power semiconductor device 100 including second trenches 160 having depths that become shallow as they become distant from the active region A and including an electric field limiting region 171 formed in the vicinity of the second trenches 160.

Referring to FIG. 7, the electric field limiting region 171 may be formed by implanting p-type impurities in the vicinity of the second trench 160.

The electric field limiting region 171 may be formed by etching the second trench and then implanting second conductive type impurities before filling an insulating material or a conductive material in the second trench.

In the case in which the trench is present, the electric field may be concentrated on a lower end portion of the trench due to a shape of the trench.

Therefore, the electric field limiting region 171 may be formed in the vicinity of the second trench 160 to prevent the electric field from being concentrated on the lower portion of the second trench 160, thereby improving a blocking voltage.

For example, the electric field limiting region 171 may be formed at only a lower end portion of the second trench 160 to prevent the electric field from being concentrated on the lower portion of the second trench 160, thereby improving the blocking voltage.

In addition, since the depths of the second trenches 160 become swallow as the second trenches 160 become distant from the active region A, the electric field may be gently extended to improve the blocking voltage.

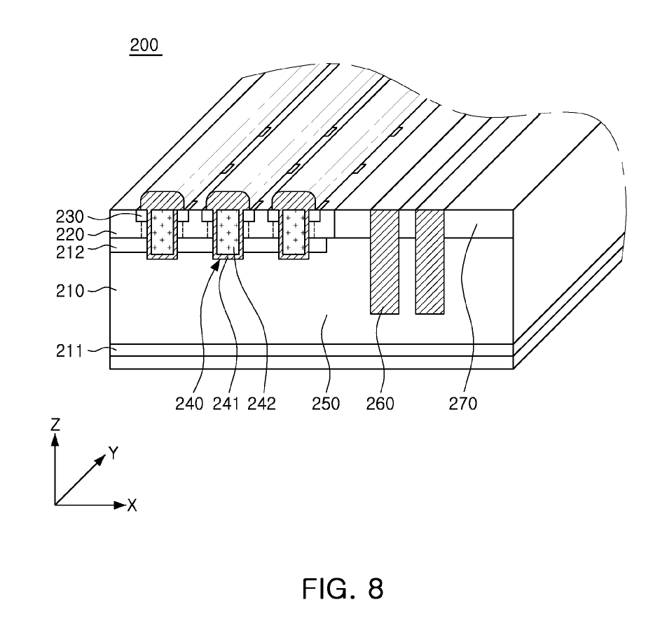

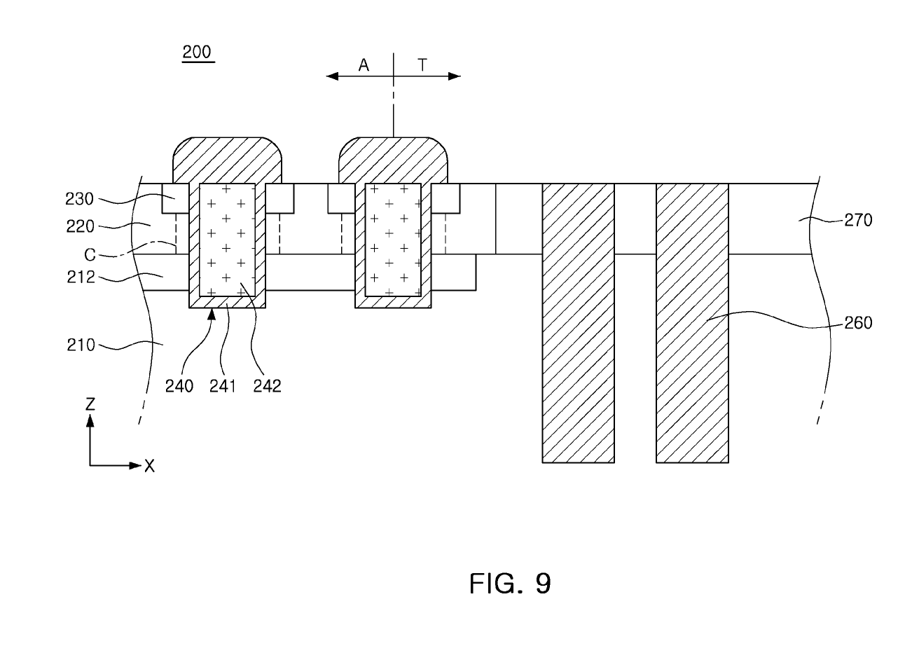

FIG. 8 is a schematic perspective view of a power semiconductor device 200 according to another exemplary embodiment of the present disclosure in which a hole accumulating region 212 is formed; and FIG. 9 is a schematic cross-sectional view illustrating an example of the power semiconductor device 200.

Contents omitted in components to be described below are the same as the contents described above.

Referring to FIGS. 8 and 9, the power semiconductor device 200 according to another exemplary embodiment of the present disclosure may include the hole accumulating region 212 formed below a channel formed at the time of a turn-on operation of the power semiconductor device 200.

The hole accumulating region 212 may be formed by implanting n-type impurities.

A concentration of impurities of the hole accumulating region 212 may be higher than that of the drift region 210.

Since the concentration of the impurities of the hole accumulating region 212 is high, holes may be accumulated below the channel.

In the case in which the holes are accumulated, a conductivity modulation phenomenon may be significantly increased at a corresponding portion, such that a turn-on voltage of the power semiconductor device 200 may be decreased.

However, since the hole accumulating region 212 is formed by implanting the n-type impurities at a high concentration, in the case of using a method of maintaining the blocking voltage by forming the p-type guard ring in the termination region according to the related art, there was a problem that the blocking voltage of the power semiconductor device is decreased.

That is, the hole accumulating region positioned between the active region A and the termination region T may decrease a blocking voltage maintaining effect of the p-type guard ring adjacent thereto, such that the blocking voltage may be decreased.

In the power semiconductor device 200 according to another exemplary embodiment of the present disclosure, the blocking voltage may be maintained by the second trench 260, such that a problem that the blocking voltage maintaining effect of the p-type guard ring is decreased does not occur.

Therefore, the power semiconductor device 200 according to another exemplary embodiment of the present disclosure may have a low turn-on voltage and may have a high blocking voltage.

Particularly, since the second trench 260 may allow the electric field to be extended in the vertical direction, a size of the termination region T may be decreased.

Since the size of the termination region T may be decreased, a size of the active region A of the power semiconductor device 200 may be relatively increased, such that performance of the power semiconductor device 200 may be improved.

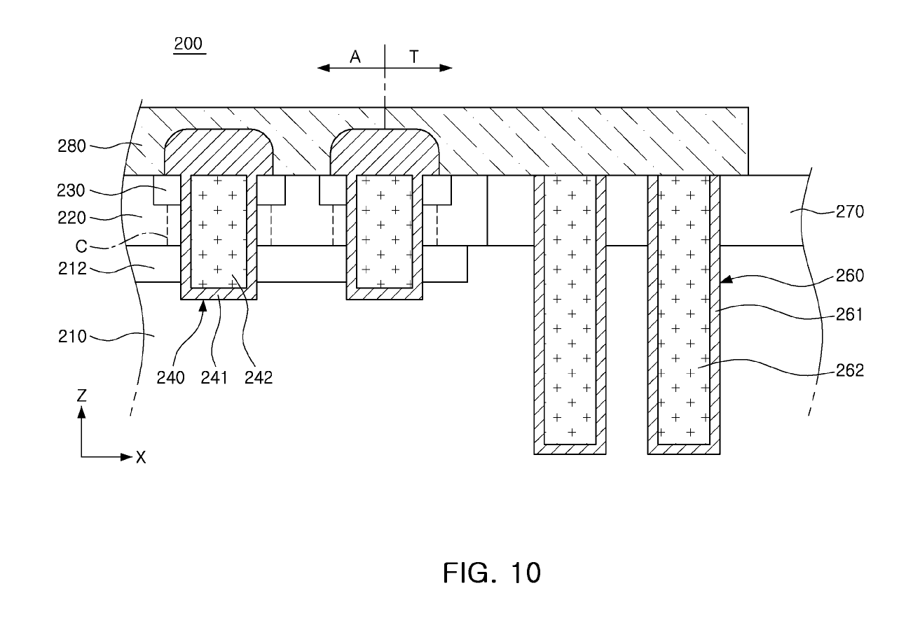

FIG. 10 is a schematic cross-sectional view illustrating another example of the power semiconductor device 200 according to another exemplary embodiment of the present disclosure including conductive materials 262 filled in the second trenches 260.

Referring to FIG. 10, the second trench 260 may have an insulating layer 261 formed on a surface thereof and may have the conductive material 262 filled therein.

Since the conductive material 262 filled in the trench 162 has an electric field of 0V, it may push the electric field.

Particularly, in the case in which the power semiconductor device 100 further includes the metal emitter layer 280 formed on the upper surfaces of the emitter region 230 and the body region 220, the emitting metal layer 280 and the second trench 260 may be electrically connected to each other.

In the case in which the metal emitter layer 280 and the second trench 260 are electrically connected to each other, the metal emitter layer 280 and the second trench 260 may have the same potential as each other.

Therefore, the second trench 260 may more easily push the electric field.

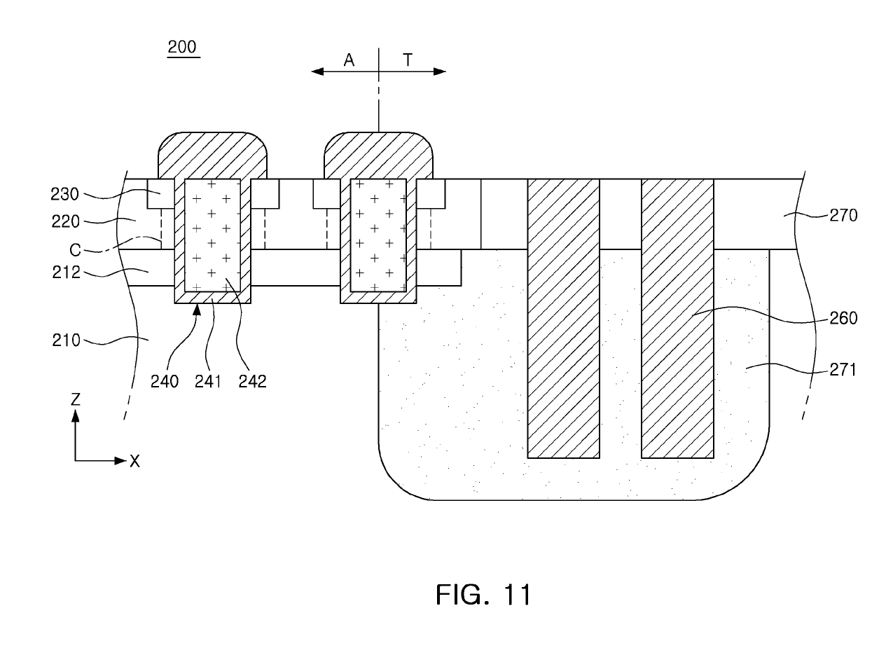

FIG. 11 is a schematic cross-sectional view illustrating another example of the power semiconductor device 200 according to another exemplary embodiment of the present disclosure including an electric field limiting region 271 formed in the vicinity of the second trenches 260.

Referring to FIG. 11, the electric field limiting region 271 may be formed by implanting p-type impurities in the vicinity of the second trench 260.

The electric field limiting region 271 may be formed by etching the second trench and then implanting second conductive type impurities before filling an insulating material or a conductive material in the second trench.

In the case in which the trench is present, the electric field may be concentrated on a lower end portion of the trench due to a shape of the trench.

Therefore, the electric field limiting region 271 may be formed in the vicinity of the second trench 260 to prevent the electric field from being concentrated on the lower portion of the second trench 260, thereby improving a blocking voltage.

For example, the electric field limiting region 271 may be formed at only a lower end portion of the second trench 260 to prevent the electric field from being concentrated on the lower portion of the second trench 260, thereby improving the blocking voltage.

Particularly, the electric field limiting region 271 may cover a portion of the hole accumulating region 212.

For example, the electric field limiting region 271 may cover the hole accumulating region 212 formed at a boundary between the active region A and the termination region T.

Therefore, a decrease in a blocking voltage maintaining effect of the electric field limiting region 271 due to the hole accumulating region 212 may be significantly suppressed.

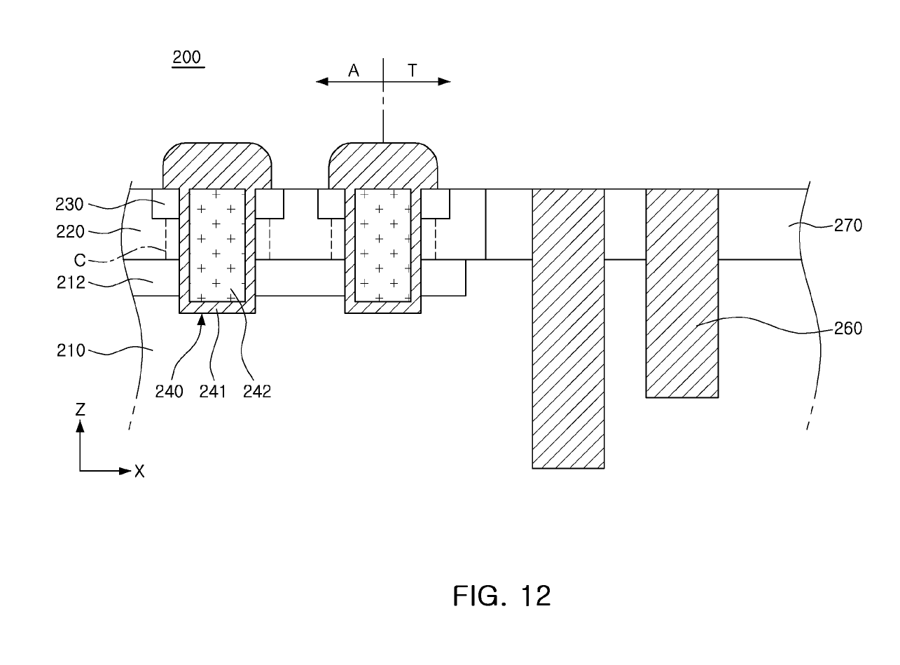

FIG. 12 is a schematic cross-sectional view illustrating another example of the power semiconductor device including second trenches 260 having depths that become shallow as they become distant from the active region A.

In the case in which two or more second trenches 260 are formed, they may have depths that become swallow as they are distant from the active region A.

Generally, the electric field may gradually become weak as it is distant from the active region.

Therefore, in the case in which the depths of the second trenches 260 become swallow as the second trenches 260 become distant from the active region A, as illustrated in FIG. 12, the blocking voltage may be more effectively improved and maintained.

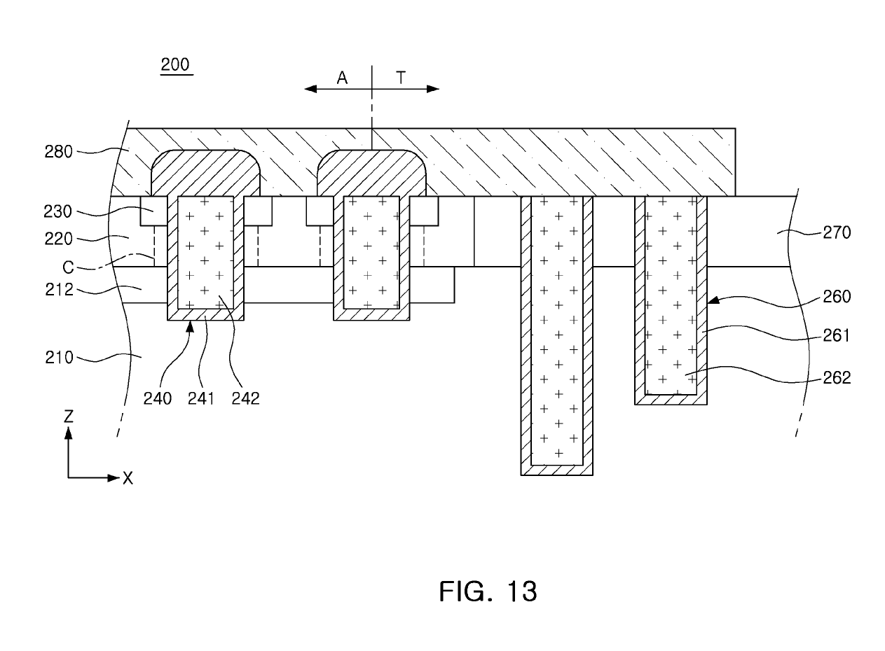

FIG. 13 is a schematic cross-sectional view illustrating another example of the power semiconductor device 200 including second trenches 260 having depths that become shallow as they become distant from the active region A and including conductive materials 262 filled in the second trenches 260.

Referring to FIG. 13, the second trench 260 may have an insulating layer 261 formed on a surface thereof and may have the conductive material 262 filled therein.

Since the conductive material 262 filled in the trench 162 has an electric field of 0V, it may push the electric field.

Particularly, in the case in which the power semiconductor device 100 further includes the metal emitter layer 180 formed on the upper surfaces of the emitter region 230 and the body region 220, the emitting metal layer 180 and the second trench 260 may be electrically connected to each other.

In the case in which the metal emitter layer 280 and the second trench 260 are electrically connected to each other, the metal emitter layer 280 and the second trench 260 may have the same potential as each other.

Therefore, the second trench 260 may more easily push the electric field.

In addition, in the case in which the depths of the second trenches 260 become swallow as the second trenches 260 become distant from the active region A, as illustrated in FIG. 13, the blocking voltage may be more effectively improved and maintained.

That is, in the case in which the second trench 260 is connected to the metal emitter layer 280 to have the same potential as that of the metal emitter layer 180, it may efficiently push the electric field. In this example, since the depths of the second trenches 260 become swallow as the second trenches 260 become distant from the active region A, a space in which the electric field is extended may be increased to improve the blocking voltage.

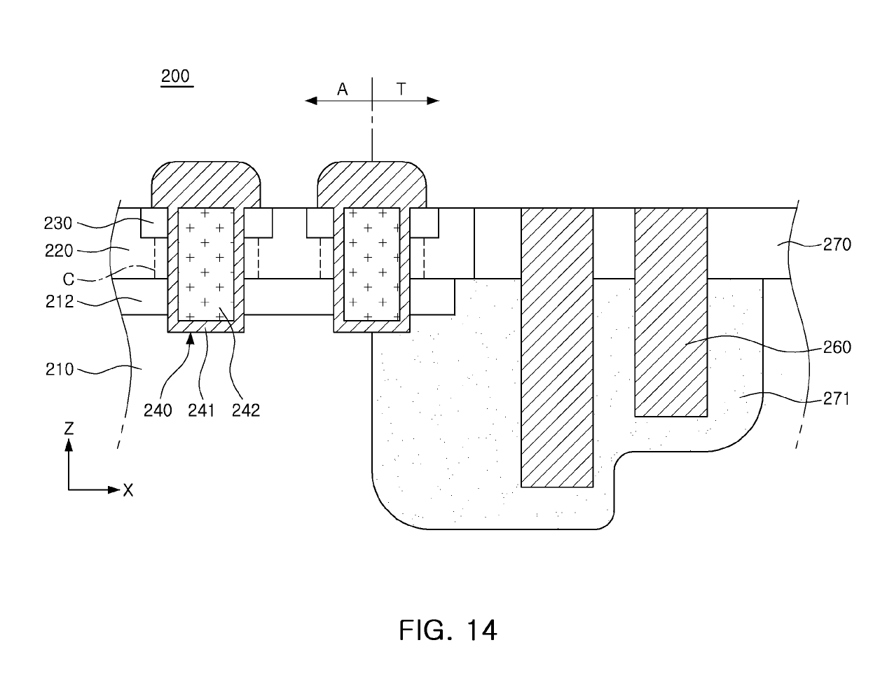

FIG. 14 is a schematic cross-sectional view illustrating another example of the power semiconductor device 200 including second trenches 260 having depths that become shallow as they become distant from the active region A and including an electric field limiting region 271 formed in the vicinity of the second trenches 260.

Referring to FIG. 14, the electric field limiting region 271 may be formed by implanting p-type impurities in the vicinity of the second trench 260.

The electric field limiting region 271 may be formed by etching the second trench and then implanting second conductive type impurities before filling an insulating material or a conductive material in the second trench.

In the case in which the trench is present, the electric field may be concentrated on a lower end portion of the trench due to a shape of the trench.

Therefore, the electric field limiting region 271 may be formed in the vicinity of the second trench 260 to prevent the electric field from being concentrated on the lower portion of the second trench 260, thereby improving a blocking voltage.

For example, the electric field limiting region 271 may be formed at only a lower end portion of the second trench 260 to prevent the electric field from being concentrated on the lower portion of the second trench 260, thereby improving the blocking voltage.

In addition, since the depths of the second trenches 260 become swallow as the second trenches 160 become distant from the active region A, the electric field may be gently extended to improve the blocking voltage.

Particularly, the electric field limiting region 271 may cover a portion of the hole accumulating region 212.

For example, the electric field limiting region 271 may cover the hole accumulating region 212 formed at a boundary between the active region A and the termination region T.

Therefore, a decrease in a blocking voltage maintaining effect of the electric field limiting region 271 due to the hole accumulating region 212 may be significantly suppressed.

As set forth above, since the power semiconductor device according to exemplary embodiments of the present disclosure includes the second trenches formed in the termination region at a depth deeper than those of the first trenches formed in the active region, in the case in which the power semiconductor device is operated in a blocking mode, the electric field may be extended in the vertical direction in the termination region.

Since the electric field may be extended in the vertical direction in the termination region and the blocking voltage may be maintained, the size of the termination region may be decreased.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device comprising:
an active region having a current flowing through a channel in the active region at the time of a turn-on operation of the power semiconductor device;
a termination region disposed in the vicinity of the active region;
a plurality of first trenches extending lengthwise in one direction in the active region; and
at least one or more second trenches extending lengthwise in one direction in the termination region,
wherein the second trench has a depth deeper than that of the first trench.

2. The power semiconductor device of claim 1, wherein the second trench has a width greater than that of the first trench.

3. The power semiconductor device of claim 1, wherein the second trench has an insulating material filled therein.

4. The power semiconductor device of claim 1, wherein the second trench includes an insulating layer formed on a surface thereof and a conductive material filled therein.

5. The power semiconductor device of claim 4, further comprising an metal emitter layer formed on the active region,
wherein the second trench has the same potential as that of the metal emitter layer.

6. The power semiconductor device of claim 1, further comprising an electric field limiting region enclosing the second trenches and having a second conductive type.

7. The power semiconductor device of claim 1, wherein the second trenches be reduced in depth away from the active region.

8. A power semiconductor device comprising:
an active region having a current flowing through a channel in the active region at the time of a turn-on operation of the power semiconductor device;
a termination region disposed in the vicinity of the active region;
a hole accumulating region disposed in the active region and below the channel of the active region;
a plurality of first trenches extending lengthwise in one direction in the active region; and
at least one or more second trenches extending lengthwise in one direction in the termination region,
wherein the second trench is formed to a depth deeper than that of the first trench.

9. The power semiconductor device of claim 8, wherein the second trench has a width greater than that of the first trench.

10. The power semiconductor device of claim 8, wherein the second trench has an insulating material filled therein.

11. The power semiconductor device of claim 8, wherein the second trench includes an insulating layer formed on a surface thereof and a conductive material filled therein.

12. The power semiconductor device of claim 11, further comprising an metal emitter layer formed on the active region,
wherein the second trench has the same potential as that of the metal emitter layer.

13. The power semiconductor device of claim 8, further comprising an electric field limiting region enclosing the second trenches and having a second conductive type.

14. The power semiconductor device of claim 13, wherein the electric field limiting region covers at least a portion of the hole accumulating region positioned in the active region and the termination region.

15. The power semiconductor device of claim 8, wherein the second trenches be reduced in depth away from the active region.
